(19) United States
(12) Patent Application Publication
(10) Pub. No.: US 2009/0309090 A1
(43) Pub. Date: Dec. 17, 2009

(54) Nanostructures and a Method for the Manufacture of the Same

(75) Inventors: Robert Morrison Bowman, Lisburn (GB); Robert James Pollard, Bangor (GB); John Martin Gregg, Holywood (GB); Finlay Doogan Morrison, Dundee (GB); James Floyd Scott, Cambridge (GB)

Correspondence Address: CHOATE, HALL & STEWART LLP, TWO INTERNATIONAL PLACE, BOSTON, MA, 02110, US

(73) Assignee: THE QUEEN'S UNIVERSITY OF BELFAST, Belfast, GB (GB)

(21) Appl. No.: 12/297,824

(22) PCT Filed: Apr. 20, 2007
(86) PCT No.: PCT/GB2007/001437

§ 371 Date: Mar. 16, 2009

(30) Foreign Application Priority Data
Apr. 21, 2006 (GB) 0607890.1

(51) Int. Cl. H01L 29/06; H01L 21/44; G11C 11/22

(52) U.S. Cl. 257/9; 438/597; 977/943; 365/145; 257/E21.476; 257/E29.005; 977/700; 977/840

(57) ABSTRACT

A nanostructure comprising a first structure comprising conductive material, which is attached to a second structure comprising one or more portions of conductive material separated by insulator material, which is attached to a third structure comprising a material in which a change can be effected. The third structure may comprise a dielectric or ferroelectric material, and the change effected in the material may be polarization of the material. The nanostructure may comprise one or more nanocapacitors, each of which comprises a part of the third structure in which a change comprising polarization may be effected. The nanocapacitors may be used to store data.

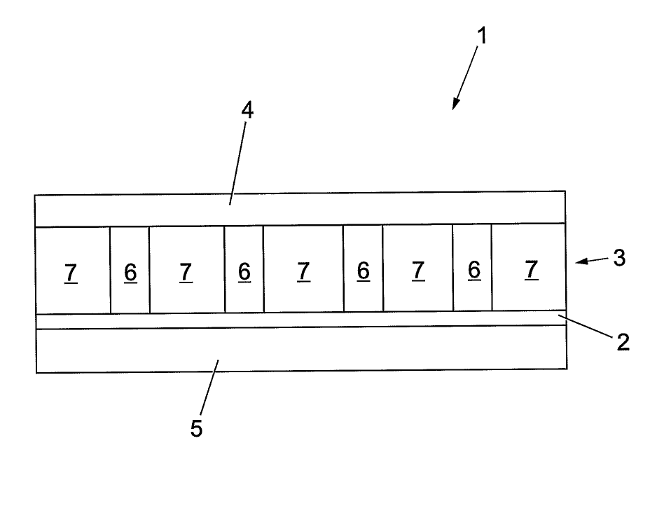

The invention relates to nanostructures and a method for the manufacture of the same.

In recent years there has been an ever-increasing interest in the development of nanostructures, for a wide variety of applications. For example, such structures can be used for data storage. With the advance of information processing technology, there is an increasing need for high density data storage. Nanostructures, due to their size, offer the potential for providing such storage. There have been many investigations of the manufacture and applications of nanostructures, and improvements are constantly being sought in this field.

According to a first aspect of the present invention there is provided a nanostructure comprising a first structure comprising conductive material, which is attached to a second structure comprising one or more portions of conductive material separated by insulator material, which is attached to a third structure comprising a material in which a change can be effected.

The third structure has a thickness which may govern the change effected in the third structure. The thickness of the third structure may be controlled to control effecting of the change in the material of the third structure.

The third structure may comprise one or more parts in which a change may be effected. The third structure may comprise a part substantially adjacent the or each portion of conductive material of the second structure, or substantially adjacent some of the portions of conductive material of the second structure in which a change may be effected. The thickness of the third structure may govern the change effected in the or each part of the material of the third structure. The thickness of the third structure may be controlled to control effecting of the change in the or each part of the material of the third structure. The thickness of the third structure may be controlled to localise effecting of the change to the or each part of the material of the third structure. When the nanostructure comprises two or more portions of conductive material in the second structure, the thickness of the third structure may be controlled to be substantially the same as the separation of the portions of conductive material of the second structure.

A change may be effected in the third structure by application of voltage thereto. A voltage may be applied to substantially all of the third structure and a change effected therein. A change may be effected in one or more of the parts of the third structure by application of voltage thereto. A voltage may be applied to substantially all of the third structure and a change effected in the one or more parts of the third structure. A localised voltage may be applied to each of the one or more parts of the third structure and a change effected in the part. The thickness of the third structure may be determined by the voltage applied thereto. The first structure may act as a first electrode and a second electrode may be provided, for application of voltage to the third structure.

The third structure may be used to store data. The third structure may be used to represent a digital 1 or 0. The or each part of the third structure in which a change may be effected may be used to store data. The or each part of the third structure in which a change may be effected may be used to represent a digital 1 or 0.

The third structure may comprise a layer of material in which a change may be effected.

It has been found that effecting of the change in the third structure can be controlled, so that the change is localised to the or each part of the third structure. This is the case even when the third structure is formed as a continuous layer, and even when a voltage is applied to substantially all of the third structure. Localisation allows isolation of the changes effected in the third structure, allowing such changes to be used to store separate pieces of data.

The third structure may comprise a dielectric material. The change effected in the dielectric material may be polarization of the dielectric material. The thickness of the dielectric material may govern the polarization effected in the dielectric material. The thickness of the dielectric material may be controlled to control effecting of the polarization in the dielectric material. The third structure may comprise a part of the dielectric material adjacent the or each portion of conductive material of the second structure, or adjacent some of the portions of conductive material of the second structure in which a change comprising polarization may be effected. A change comprising polarization may be effected in the one or more parts of the third structure by application of voltage thereto. A voltage may be applied to substantially all of the third structure and a change comprising polarization effected in the one or more parts of the third structure. A localised voltage may be applied to each of the one or more parts of the third structure and a change comprising polarization effected in the part. A polarization may be effected in the or each part of the dielectric material due to electrical contact between the part of the dielectric material and a conductive portion of the second structure, and between the conductive portion of the second structure and the first structure. The nanostructure may comprise one or more nanocapacitors, each of which comprises a part of the third structure in which a change comprising polarization may be effected. The first structure may act as a first electrode of the nanocapacitors and a second electrode is provided. The or each or some of the nanocapacitors may be used to store data. The or each or some of the nanocapacitors may be used to store a polarization used to represent a digital 1 or 0.

The third structure may comprise a ferroelectric material. The change effected in the ferroelectric material may be polarization of the ferroelectric material. The thickness of the ferroelectric material may govern the polarization effected in the ferroelectric material. The thickness of the ferroelectric material may be controlled to control effecting of the polarization in the ferroelectric material. The third structure may comprise a part of the ferroelectric material adjacent the or each portion of conductive material of the second structure, or adjacent some of the portions of conductive material of the second structure in which a change comprising polarization may be effected. A change comprising polarization may be effected in the one or more parts of the third structure by application of voltage thereto. A voltage may be applied to substantially all of the third structure and a change comprising polarization effected in the one or more parts of the third structure. A localised voltage may be applied to each of the one or more parts of the third structure and a change comprising polarization effected in the part. A polarization may be effected in the or each part of the ferroelectric material due to electrical contact between the part of the ferroelectric material and a conductive portion of the second structure, and between the conductive portion of the second structure and the first structure. The nanostructure may comprise one or more nanocapacitors, each of which comprises a part of the third structure in which a change comprising polarization may be effected. The first structure may act as a first electrode of the nanocapacitors and a second electrode is provided. The or each or at least some of the nanocapacitors may be used to store data. The or each or at least some of the nanocapacitors may be used to store a polarization used to represent a digital 1 or 0.

The use of a ferroelectric material for the third structure is particularly advantageous, as this type of material retains polarization well. The nanostructure comprising a ferroelectric material third structure, may therefore be particularly useful for the storage of data. The nanostructure comprising a ferroelectric material third structure may be used to form a FeRAM device or other ferromagnetic based storage system.

The third structure may comprise an ovonic material. The change effected in the ovonic material may be a phase change of the ovonic material. The phase change may be from a crystalline phase to an amorphous phase or vice versa. The thickness of the ovonic material may govern the phase change effected in the ovonic material. The thickness of the ovonic material may be controlled to control effecting the phase change in the ovonic material. The third structure may comprise a part of the ovonic material adjacent the or each portion of conductive material of the second structure, or adjacent some of the portions of conductive material of the second structure in which a phase change may be effected. A phase change may be effected in the or each part of the ovonic material due to electrical contact between the part of the ovonic material and a conductive portion of the second structure, and between the conductive portion of the second structure and the first structure. The or each part of the ovonic material of the third structure in which a phase change may be effected may be used to store data. The or each part of the ovonic material of the third structure in which a phase change may be effected may be used to represent a digital 1 or 0.

A phase change of the ovonic material of the third structure, may be effected by applying a change in resistance to the third structure. When a phase change is effected in one or more parts of the ovonic material, this may be effected by applying a separate, localised change in resistance to each part of the material.

The first structure may comprise one or more layers. When the first structure comprises two or more layers, these may be attached together. The or each layer may comprise a metallic conductive material, for example any of tantalum, platinum, iridium, SrRuO₃, (La_{1/2}Sr_{1/2})CoO₃, or combinations thereof. The or each layer may act as an electrode. The first structure may have a thickness in the region of approximately 10 nm to approximately 100 nm.

The second structure may comprise one or more layers. The or each layer or at least some of the layers may comprise one or more portions of conductive material separated by insulator material. The or each portion of the conductive material of the second structure may have a diameter in the region of approximately 10 nm to approximately 100 nm. When the second structure comprises two or more portions of conductive material, these may have a separation in the region of approximately 10 nm to approximately 100 nm. When the nanostructure acts as a data store, utilising effecting a change adjacent the portions of conductive material, the very small separation of the portions of conductive material, provides a high density data store. The one or more portions of conductive material of the second structure may comprise one or more pillars of the conductive material. The or each pillar may comprise a first end which is attached to the first structure, and a second end which is attached to the third structure. The first end of the or each pillar may be in electrically contact with the first structure. The second end of the or each pillar may be in electrically contact with the third structure. The or each pillar of the conductive material may form a wire of the conductive material. The conductive material of the second structure may comprise a metallic material, for example, any of platinum, gold, copper, nickel, or combinations thereof. The insulator material of the second structure may comprise alumina.

The nanostructure may further comprise a fourth structure. The fourth structure may be attached to the first structure. The fourth structure may act as a substrate for the nanostructure, providing a mechanical support for the nanostructure. The fourth structure may comprise a layer. The fourth structure may comprise silicon. The fourth structure may comprise a glass material.

The nanostructure may have a thickness in the region of approximately 50 nm to approximately 1000 nm.

According to a second aspect of the present invention there is provided a method of manufacturing a nanostructure according to the first aspect of the invention, comprising the steps of:

forming the first structure,
forming the second structure, by forming at least one layer of insulator material comprising one or more pores on a surface of the first structure, placing conductive material in the or each pore to form the one or more portions of conductive material separated by insulator material, and
forming the third structure on a surface of the second structure.

The first structure may be formed on a substrate structure. The first structure may be formed on the substrate structure by a deposition method, for example, a sputtering deposition method, or a PLD method, or an electrodeposition method, or an evaporation method, or a chemical method.

Forming a layer of insulator material on the surface of the first structure may comprise placing at least one layer of conductive material on the first structure, and treating the layer of conductive material to form a layer of insulator material. Treating the layer of conductive material may comprise anodisation of the conductive material to form the insulator material. Treating the layer of conductive material to form the insulator material may cause formation of the one or more pores in the insulator material. The layer of conductive material may comprise aluminium, which is treated by anodisation to form the insulator material comprising alumina. Treating the aluminium conductive material by anodisation may also form one or more pores in the alumina insulator material.

Formation of the one or more pores in the insulator material may further comprise a process to extend the or each pore to reach the first structure. This may involve a milling process, for example an argon ion milling process, or a chemical etching process.

Conductive material may be placed in the or each or at least some of the pores of the insulator material. This may be achieved by, for example, an electro-deposition method, or a physical vapour deposition method or a chemical deposition method.

The at least one insulator layer may comprise an irregular pattern of pores. The irregular pattern of pores may be dictated by the inherent structure of the insulator material. The insulator layer may comprise a desired pattern of pores. The desired pattern of pores may be a regular pattern of pores. This may be achieved by imprinting the at least one conductive material prior to treatment thereof to form the insulator material.

The pores, and hence the portions of conductive material, may have a diameter in the region of approximately 20 nm to approximately 40 nm. The separation of the pores, and hence the portions of conductive material, may be in the region of approximately 10 nm to approximately 100 nm, for example approximately 50 nm to approximately 100 nm.

The third structure may be formed on the second structure by, for example, a MIST method, or a pulsed laser deposition method, or a chemical solution deposition method, or an evaporation method. Forming the third structure may involve heating the nanostructure to a temperature of approximately 600° C. This may impose limitations on the type of conductive material used in the second structure.

According to a third aspect of the invention there is provided a data storage device comprising at least one nanostructure according to the first aspect of the invention.

The data storage device may comprise an array of nanostructures.

According to a fourth aspect of the invention there is provided a sensor comprising at least one nanostructure according to the first aspect of the invention.

The sensor may comprise an array of nanostructures, and may provide a high resolution sensor array.

An embodiment of the invention will now be described, by way of example only, with reference to the accompanying drawing, which is a schematic representation of a nanostructure according to the first aspect of the invention.

The FIGURE shows a cross sectional view of a nanostructure 1. This comprises a first structure 2 in the form of a layer of conductive material, a second structure 3 in the form of a layer of conductive material and insulator material, and a third structure 4 in the form of a layer comprising a material in which a change may be effected. The nanostructure 1 may comprise one or more further layers, deposited onto the third structure 4.

The first structure 2 is formed on a substrate 5, by, for example, a sputter coating technique. The substrate 5 provides a mechanical support for the first, second and third structures. The substrate comprises, for example, a semiconductor, such as silicon, or insulator, or dielectric, or metallic material.

The first structure 2 comprises a layer of tantalum and is formed on the substrate 5 by deposition. In this embodiment, the first structure 2 comprises a single layer of tantalum, although it will be appreciated that the first structure could comprise a number of layers formed from different conductive materials, for example tantalum and gold. A multi-layer first structure may be used to provide sufficiently strong adhesion of the first structure to the substrate, whilst maintaining reasonable conductivity of the first structure.

The second structure 3 comprises a plurality of portions of conductive material 6, comprising platinum, which are separated by insulator material 7, comprising alumina. The second structure 3 is formed on a surface of the first structure 2 by firstly depositing a thin film layer of aluminium (of thickness of the order of up to 450 nm) on the surface of the first structure 2. The deposition may comprise a sputter coating technique. (Small amounts of oxygen may be added to the aluminium thin film, to improve the thermal stability of pore structures formed in the film). The aluminium layer is then anodised. A combined structure formed from the substrate, first structure and second structure, is placed in an electrolytic cell containing weak sulphuric acid (approximately 0.3 M), which is cooled to a temperature of approximately 2° C. The combined structure is used as an anode of the electrolytic cell, and platinum is used as the cathode of the cell. A voltage of approximately 20V is applied to the cell, and this induces oxidation of the aluminium layer. This transforms the aluminium to alumina, and also forms a plurality of pores in the alumina. The pores may extend through the whole thickness of the alumina layer, from the surface of the second structure 3 which is adjacent the first structure 2 to the surface of the second structure 3 which will be adjacent the third structure 4. However, if this is not the case, the alumina may be etched, using for example a sodium hydroxide solution of approximately 0.1 M, to ensure that the pores extend through the whole thickness of the second structure. Once the pores have been formed, and etched if necessary, platinum is placed in each of the pores, by an electro-chemical deposition process, to form the portions of conductive material 6. The combined structure is placed in a further electrolytic cell, containing an approximately 0.2 M chloroplatinic acid salt-solution, and a deposition voltage of typically −0.1V applied. The combined structure is used as an electrode of the electrolytic cell, and is placed in the cell such that the only conducting regions of the combined structure which are exposed to the salt-solution, are those at the bottom of the pores formed in the alumina. Electrolytic deposition of platinum will therefore occur only within the pores, forming the platinum portions of conductive material 6. The deposition current in the electrolytic cell is monitored during deposition of the platinum, and a sudden increase in the current is observed when the platinum deposition reaches the top of the pores. Deposition is continued until increase of the current ceases. At this point platinum has been deposited in the pores and also in a continuous film on the surface of the combined structure. The combined structure is then removed from the electrolytic cell, and is then blanket argon ion-etched at low angle to remove the film of platinum, leaving outer portions of the platinum portions 6 level with outer portions of the alumina. The platinum portions of conductive material 6 so formed, extend to and abut the surface of the first structure 2, and form an electrical contact with the conductive tantalum layer of this structure. The platinum portions of conductive material 6 of the second structure 3 are separated from each other by the alumina, which is an insulator material. Hence the conductive platinum portions 6 are electrically separated from each other.

Without pretreatment of the aluminium before anodisation, the pores will form in the alumina according to the inherent physical structure of the alumina. This will create an semi-ordered array of pores in the alumina. Such a structure could have applications, however a regular array of pores would provide a nanostructure capable of being readily used in many current applications. Prior to anodisation of the aluminium layer, this layer can be treated to provide a regular array of indentations in its free surface, i.e. the surface not attached to the first structure 2. Such indentations will result in the formation of a pore at each indentation, and hence will result in the formation of a regular array of pores, or pores in predetermined positions.

The diameter of the pores and hence the portions of conductive material 6 can be in the region of approximately 20 nm to approximately 40 nm. The separation of the pores and hence the portions of conductive material 6 of the second structure 3, can be controlled by controlling the separation of the indentations made in the aluminium layer. The separation of the platinum portions of conductive material 6 can be in the region of approximately 10 nm to approximately 100 nm, for example approximately 50 nm to approximately 100 nm.

The third structure 4 comprises a ferroelectric material, such as barium titanate or lead zirconium titanate. This is deposited on the second structure 3, by, for example, pulsed laser deposition or a MIST chemical solution deposition method or a spin-coat sol-gel process, so that it covers substantially all of the second structure 3. The ferroelectric material is in contact with the plurality of platinum portions of conductive material 6 of the second structure 3, and forms an electrical contact with these portions.

The ferroelectric material is capable of having a polarization effected in it. A polarization can be effected by the application of a voltage to the ferroelectric material, as the ferroelectric material is in electrical contact with the conductive first structure 2 via the portions of conductive material 6 of the second structure 3.

The first structure 2, comprising tantalum, acts as a first electrode, and the third structure 4, comprising the ferroelectric material, acts as an active layer (storing information). A further layer, for example comprising Au, may be deposited onto the third structure 4, and this acts as a second electrode. A voltage is applied to substantially all of the ferroelectric material of the third structure 4. This causes a plurality of localised polarizations to be effected in the ferroelectric material, due to localised electric fields generated in the ferroelectric material by the voltage in regions of the ferroelectric material adjacent the portions of conductive material 6 of the second structure 3. This is despite the voltage being applied to substantially all of the third structure 3, and the ferroelectric material of the third structure 3 being in the form of a continuous layer. The thickness of the ferroelectric material is controlled to minimise interference between adjacent polarizations. This may occur due to lateral electric field-spreading through the ferroelectric material. Specifically, the ferroelectric material is made thin enough to minimise the interference between polarizations. The nanostructure 1 so formed thus provides a plurality of nanocapacitors. The dimensions of the polarization of each nanocapacitor will be defined by the electric field emanating from the portion of conductive material 6 of the nanocapacitor and causing the polarization. A nanostructure comprising a high density of nanocapacitors is realised, even with a ferroelectric third structure in the form of a continuous layer.

As an alternative to the above, a localised voltage may be applied to the ferroelectric third structure 4, at each, or at least some of the regions of the ferroelectric material adjacent a portion of conductive material 6 of the second structure 3. This may be achieved by using a probe, for example of a scanning probe microscope, as the second electrode, which is moved over the nanostructure 1 to apply a localised voltage to one or more of the regions of ferroelectric material of the third structure 4. Alternatively, this may be achieved by using an array of probes as second electrodes, which apply a localised voltage to regions of ferroelectric material of the third structure 4. The width of the probe or probes should be less than that the spacing of the portions of conductive material 6 of the second structure 3. Alternatively, this may be achieved by depositing a layer onto the ferroelectric third structure 4, which layer acts as the second electrode and is patterned such that when a voltage is applied thereto, a plurality of localised voltages is applied to the ferroelectric third structure 4, i.e. the patterned layer provides an array of electrodes. The or each localised voltage applied to the third structure 4, causes a localised polarization to be effected in the ferroelectric material thereof, due to a localised electric field generated in the ferroelectric material by the voltage in a region of the ferroelectric material adjacent a portion of conductive material 6 of the second structure 3. As above, the nanostructure 1 so formed again provides a plurality of nanocapacitors. The dimensions of the polarization of each nanocapacitor will be defined by the electric field emanating from the portion of conductive material 6 of the nanocapacitor and causing the polarization. A nanostructure comprising a high density of nanocapacitors is realised. Each nanocapacitor of this nanostructure can be individually addressed. This is due to the provision of the second electrode as either a mobile probe, array of probes or a patterned layer. This may also be achieved by providing the first electrode, i.e. the first structure 2, in the form of a patterned layer comprising an array of electrodes.

Each polarization produces in the ferroelectric third structure 4 can be well localised, and due to the use of a ferroelectric material can be maintained in this material for a considerable length of time. Each polarization may be either an ‘up’ polarization or a ‘down’ polarization. Each polarization can therefore be used to represent a digital 1 or 0. Thus the nanostructure can be used as a storage device, storing a plurality of binary bits. As the separation of the portions of conductive material 6 of the second structure 3, and hence of the polarizations in the ferroelectric material of the third structure 4, can be made of the order of 10 nm to 100 nm, this provides the potential of a very high density storage device or a high resolution sensor. The dimensions of the polarizations, and their spacing, result in a nominal bit density of the order of 10¹¹ to 10¹² bits per square inch. This sets a new paradigm in hard-wired solid-state memory. The direction of the polarizations may be switched, by switching the polarity of the voltage applied to the ferroelectric material of the third structure 4.

The embodiment has been described as comprising a ferroelectric material, but it will be appreciated that other materials in which a change can be effected can be used, such as other dielectric materials, ferromagnetic materials, ovonic materials, polymeric or molecular materials.

What is claimed is:

1. A nanostructure comprising a first structure comprising conductive material, which is attached to a second structure comprising one or more portions of conductive material separated by insulator material, which is attached to a third structure comprising a material in which a change can be effected.

2. A nanostructure according to claim 1, in which the third structure has a thickness which governs the change effected in the third structure.

3. A nanostructure according to claim 1, in which the thickness of the third structure is controlled to control effecting of the change in the material of the third structure.

4. A nanostructure according to claim 1, in which the third structure comprises one or more parts in which a change may be effected.

5. A nanostructure according to claim 4, in which the third structure comprises a part adjacent the or each portion of conductive material of the second structure, or adjacent some of the portions of conductive material of the second structure in which a change may be effected.

6. A nanostructure according to claim 4, in which the thickness of the third structure is controlled to localise effecting of the change to the or each part of the material of the third structure.

7. A nanostructure according to claim 1, comprising two or more portions of conductive material in the second structure, wherein the thickness of the third structure is controlled to be substantially the same as the separation of the portions of conductive material of the second structure.

8. A nanostructure according to claim 4, in which a change is effected in the one or more of the parts of the third structure by application of voltage thereto.

9. A nanostructure according to claim 8, in which a voltage is applied to substantially all of the third structure and a change effected in the one or more parts of the third structure.

10. A nanostructure according to claim 8, in which a localised voltage is applied to each of the one or more parts of the third structure and a change effected in the part.

11. A nanostructure according to claim 4, in which the or each part of the third structure in which a change may be effected is used to store data.

12. A nanostructure according to claim 1, in which the third structure comprises a dielectric material.

13. A nanostructure according to claim 12, in which the change effected in the dielectric material is polarization of the dielectric material.

14. A nanostructure according to claim 12, in which the third structure comprises a part of the dielectric material adjacent the or each portion of conductive material of the second structure, or adjacent some of the portions of conductive material of the second structure in which a change comprising polarization may be effected, due to electrical contact between the part of the dielectric material and a conductive portion of the second structure, and between the conductive portion of the second structure and the first structure.

15. A nanostructure according to claim 1 in which the third structure comprises a ferroelectric material.

16. A nanostructure according to claim 15, in which the change effected in the ferroelectric material is polarization of the ferroelectric material.

17. A nanostructure according to claim 15, in which the third structure comprises a part of the ferroelectric material adjacent the or each portion of conductive material of the second structure, or adjacent some of the portions of conductive material of the second structure in which a change comprising polarization may be effected, due to electrical contact between the part of the ferroelectric material and a conductive portion of the second structure, and between the conductive portion of the second structure and the first structure.

18. A nanostructure according to claim 14, comprising one or more nanocapacitors, each of which comprises a part of the third structure in which a change comprising polarization may be effected.

19. A nanostructure according to claim 18, in which the or each nanocapacitor or at least some of the nanocapacitors is used to store data.

20. A nanostructure according to claim 18, in which the or each nanocapacitor or at least some of the nanocapacitors is used to store a polarization used to represent a digital 1 or 0.

21. A nanostructure according to claim 1, in which the third structure comprises an ovonic material.

22. A nanostructure according to claim 21, in which the change effected in the ovonic material is a phase change of the ovonic material.

23. A nanostructure according to claim 1 in which the or each portion of the conductive material of the second structure may have a diameter in the region of approximately 10 nm to approximately 100 nm.

24. A method of manufacturing a nanostructure according to claim 1, comprising the steps of: forming the first structure, forming the second structure, by forming at least one layer of insulator material comprising one or more pores on a surface of the first structure, placing conductive material in the or each pore to form the one or more portions of conductive material separated by insulator material, and forming the third structure on a surface of the second structure.

25. A method according to claim 24, in which forming a layer of insulator material on the surface of the first structure comprises placing at least one layer of conductive material on the first structure, and treating the layer of conductive material to form a layer of insulator material.

26. A method according to claim 25, in which treating the layer of conductive material comprises anodisation of the conductive material to form the insulator material.

27. A method according to claim 25, in which treating the layer of conductive material to form the insulator material causes formation of the one or more pores in the insulator material.

28. A data storage device comprising at least one nanostructure according to claim 1.

29. A sensor comprising at least one nanostructure according to claim 1.
